(19) United States
(12) Patent Application Publication
(10) Pub. No.: US 2009/0050191 A1
(43) Pub. Date: Feb. 26, 2009

(54) System and Method for Solar Tracking

(75) Inventors: Peter Young, San Francisco, CA (US); Stephen J. Horne, El Granada, CA (US)

Correspondence Address: THE MUELLER LAW OFFICE, P.C., 12951 Harwick Lane, San Diego, CA, 92130, US

(73) Assignee: Sol Focus, Inc., Mountain View, CA (US)

(21) Appl. No.: 11/843,624

(22) Filed: Aug. 22, 2007

(51) Int. Cl. H01L 31/042; G01J 1/20

(52) U.S. Cl. 136/246; 250/203.1

(57) ABSTRACT

The present invention is a solar tracking system which utilizes three supports arranged in a generally tripod configuration. In one embodiment, two of the supports are linear actuators, and the third support is a stationary universally pivoting joint such as a ball and socket joint. The tracking system may include cross-supports for increased stability, a linear rail for additional range of motion, and a mounting base to facilitate installation. This solar tracking system offers a stable, cost-effective design which is also capable of moving the solar module into an optional stowed position.

### BACKGROUND OF THE INVENTION

In the increasingly important field of renewable energy production, solar power is a highly promising technology. This technology employs solar cells, also known as photovoltaic (PV) cells, to convert solar radiation into direct current electricity. Solar cells may be arranged into arrays of flat panels, in which sunlight directly impinges upon large surface areas of solar cells. Or, solar cells may be used in solar concentrators, in which mirrors and lenses reflect and focus solar energy onto a much smaller solar cell. While the efficiency of any solar power system is largely quantified by the ability of the solar panel to convert solar energy into electricity, the ability of the solar energy system to track the sun's movements also has a large effect on a solar power system's efficiency. That is, solar tracking adjusts the angle of the solar panel to maximize the intensity of the sunlight being collected.

One type of tracking system utilizes pedestal-mounted designs, in which a solar module is generally centered on a vertical pole, or pedestal, which is implanted into the ground. Various mechanical linkages and motors are then used to tilt the panel on the support pole in one or two axes according to the sun's movements. A strong disadvantage of pedestal-mounted systems is that an expansive solar module atop a single pole serves a large cantilever, requiring heavy frames and materials to resist the high wind loads resulting from this design.

In addition to pedestal-mounted designs, many other tracking systems have utilized combinations of sliding rails, pin joints, ball-and-sockets, rotating wheels, and more. These non-pedestal designs involve multiple supports, typically located around the perimeter of the solar module, to anchor and control the module's movement. For instance, U.S. Pat. No. 5,404,868 entitled “Apparatus Using a Balloon Supported Reflective Surface for Reflecting Light from the Sun,” describes a heliostat using multiple control tethers/rods to control the angle of a balloon-supported reflecting surface. U.S. Pat. No. 4,930,493 entitled “Multi-Lever Rim-Drive Heliostat” discloses a circular, ring-mounted reflector which is supported by a pair of levers diametrically opposite, and a third lever located below and mid-way between the connections of the lever pair. The three levers use an assembly of linkages to turn the reflector to its desired position, which can include turning the reflector face-down to a protective stowed position. The Tetra-Track system of Dobontech employs a central radius wheel combined with telescopic actuators on opposite sides of the wheel to achieve tracking in two axes.

While numerous tracking systems have been designed and implemented, none have achieved widespread commercial success. Thus, the need exists for continuous improvement in simplified, low-cost solar tracking systems which provide reliable stability and an adequate range of movement to track the sun's movement at various latitudes around the globe.

### SUMMARY OF THE INVENTION

The present invention is a solar tracking system which utilizes three supports arranged in a generally tripod configuration. In one embodiment, two of the supports are linear actuators, and the third support is a stationary universally pivoting joint such as a ball and socket joint. The tracking system may additionally include a cross-brace component, or a mounting base to facilitate installation. The tracking system offers a stable, cost-effective design which is also capable of moving the solar module into an optional stowed position.

### BRIEF DESCRIPTION OF THE DRAWINGS

FIG. 1A is a perspective view of a solar tracking system;

FIG. 1B shows a perspective view of a solar tracking system with the solar module in a tilted position;

FIG. 2 illustrates a side view of solar tracking system with the solar module in a stowed position;

FIG. 3 provides a perspective view of a solar tracking system with a mounting frame;

FIG. 4 shows a rear perspective view of a solar tracking system utilizing a cross-brace rod;

FIG. 5 depicts a rear perspective view of a solar tracking system with a linear actuator serving as a cross-brace;

FIG. 6A is a perspective view of linear actuators in a crossed configuration;

FIG. 6B is a perspective view of the system of 6A moved into a stowed position;

FIG. 7A is a perspective view of a system in which one of the supports is mounted on a rail; and

FIG. 7B is a side view of the rail system in a stowed position.

### DETAILED DESCRIPTION OF THE EMBODIMENTS

Reference now will be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For instance, features illustrated or described as part of one embodiment may be used on another embodiment to yield a still further embodiment. Thus, it is intended that the present subject matter covers such modifications and variations as come within the scope of the appended claims and their equivalents.

The current invention provides a low-cost solar tracking system which provides reliable stability with an adequate range of movement to track the sun's movement at various latitudes around the globe. The design of the current invention utilizes a three-point support system which improves resistance to wind loads compared to conventional pedestal designs. The supports for this tracking system involve simple linear actuators and ball joints, thus lowering the cost and improving manufacturability over previous designs involving multi-arm linkages and greater numbers of support components. A pre-fabricated mounting base enables faster and more reliable installation in the field. This solar tracker has the ability to assume a stowed position for protection against environmental factors, and is amenable to having a small installation footprint so that the maximum number of solar modules per unit area may be installed.

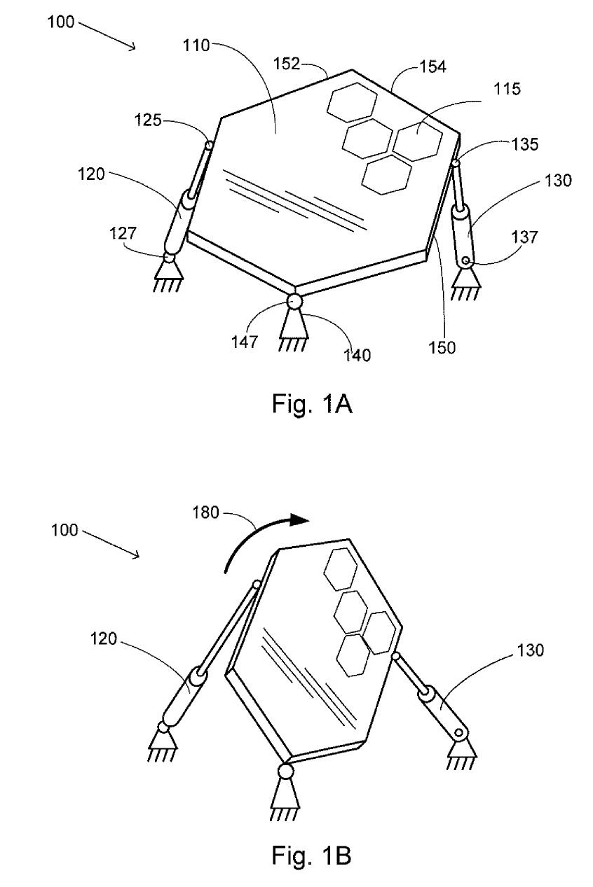

With reference to FIG. 1A, an exemplary perspective view of the present invention is shown. Solar tracking system 100 comprises solar module 110, a first linear actuator 120, a second support arm 130, and a stationary support 140. In this embodiment, the second support arm 130 is shown as a linear actuator but may be a support arm of fixed length if a more limited range of motion is acceptable. Linear actuators 120 and 130 may be, for example, pneumatic, hydraulic, or screw actuators. Stationary support 140 is approximately centered on the bottom edge of the module, although it may be located off-centered if desired. Solar arrays 115 are mounted on solar module 110, shown in this figure as only partially covering the module for clarity. This system of three supports without complex linkages offers an inexpensive design which still provides a stable construction and adequate range of motion.

In this exemplary configuration of FIG. 1A, linear actuators 120 and 130 are pivotally coupled to solar module 110 with universally pivoting joints 125 and 135, respectively. The universally pivoting joints, such as ball and socket joints, allow for pivoting between the coupled pieces in any direction. Joints 125 and 135 are located on opposite sides of module 110, and are mounted on the edge faces 150. Alternatively, linear actuators 120 and 130 may be located, for example, on adjacent edges 152 and 154, or may be mounted on the underside of solar module 110. The supports 120 and 140 in this embodiment are attached to a fixed ground surface with universally pivoting joints 127 and 147, respectively, while support arm 130 is coupled to ground with hinge joint 137. The hinge joint 137 aids in constraining the degrees of freedom in the solar tracking system 100 relative to the multiple degrees of freedom in universally pivoting joints 127 and 147. The term “ground” may refer to actual installation to the earth itself, or may refer to another mounting surface such as a rooftop. Installation to the ground would involve measuring and marking the locations at which the joints 127, 137, and 147 should be placed, and then attaching the joints to the ground at the specified locations.

Note that the trajectory of the sun varies greatly at different latitudes around the globe. Latitudes farther from the equator require a solar module to be at steeper angles relative to horizontal than those nearer the equator. Thus, the actual dimensions of the three supports of the solar tracking system of FIG. 1A can vary greatly in order to achieve the necessary angles at which to properly track the sun's rays. For example, in a site which requires the solar module to be in near-horizontal positions, actuator 120, actuator 130, and support 140 may be of similar height. In contrast, where the solar module 110 must be at elevated angles, actuators 120 and 130 may have a nominal length distinctly greater than the height of support 140. The effect of latitude on module positioning can similarly allow for other types of mechanical joints to be substituted for ball and socket joints. For instance, where a reduced range of motion is acceptable, ball and socket joints 125 and 135 may be replaced by sliding pin joints since fewer degrees of freedom are necessary.

Moving to FIG. 1B, the same solar tracking system 100 of FIG. 1A is now shown in a tilted position as indicated by arrow 180. Linear actuator 120 is depicted in an extended and upwardly rotated position, while actuator 130 has varied its length to rotate downward and to tilt the solar module 110. Note that the shape of solar module 110 in FIGS. 1A and 1B is shown to be hexagonal, such that the angled corners allow for clearance from the ground during movement of the module. However, other module shapes are possible, such as circular, rounded, triangular, rectangular, or other polygonal shapes, depending on the surface area desired for solar energy collection and the shape of the solar panels being mounted on the module.

To achieve movement of the linear actuators and solar module, the solar tracking system requires use of a control system, not shown. The control system may comprise a computerized system pre-programmed with tilt angles corresponding to known movements of the sun, photo sensors on the solar module to provide differential solar intensity values, manual input methods, or other means. Signals derived from the control system cause the linear actuators to move via linear encoders, pneumatic cylinders, or other methods as appropriate to the specific type of actuator being utilized. Movement of the support arms, which are typically linear actuators, results in the solar module shifting angle or position.

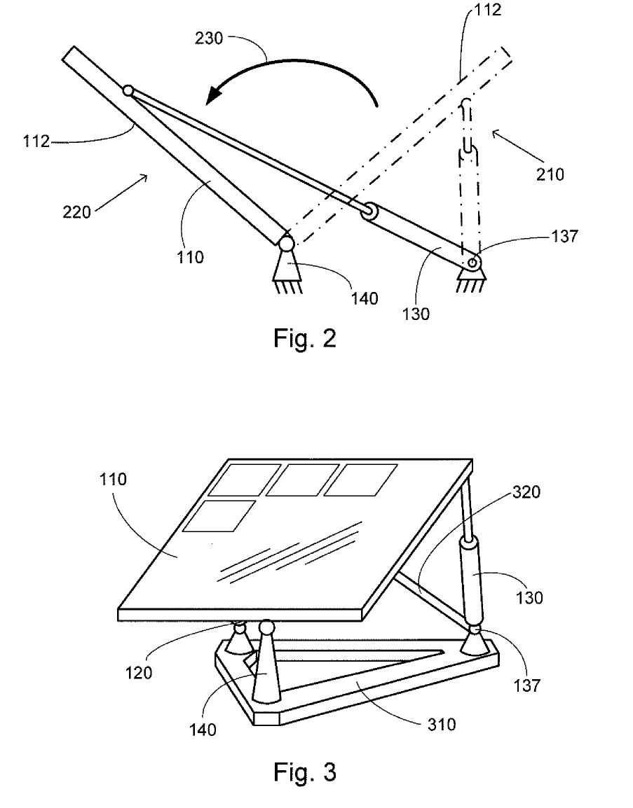

Turning now to FIG. 2, this side view illustrates the ability of the present invention to move the solar module 110 from an active position 210 into a stowed position 220. In this embodiment, hinge joint 137 is oriented such that its axis of rotation allows the solar module 110 to rotate toward stationary support 140. By inverting the module 110 as represented by arrow 230 so that the active face 112 containing the arrays is at least partially facing the ground, the tracking system provides the solar arrays some protection from environmental conditions such as rain, hail, and snow. The stowed position is achieved by extending actuator 130 and actuator 120 (not shown) so that solar module 110 rotates around support 140.

FIG. 3 depicts an alternative configuration of the tracking system using a rectangular-shaped solar module 110, and adding a mounting base 310 and a cross-brace 320. Cross-brace 320 is typically a linear actuator, and connects linear actuator 120 with actuator 130 to provide additional stability. Note that this embodiment demonstrates the ability of joint 137 to be configured as a universally pivoting joint rather than a hinge joint of FIG. 1.

The mounting base 310 of FIG. 3 improves the accuracy of positioning the supports 120, 130, and 140 during installation by providing supports which are pre-mounted to the base, or alternatively by providing pre-drilled holes at which the supports are to be attached during installation. In the illustrated configuration, the mounting base is a solid, approximately triangular frame, for example made of wood, to which the three supports 120, 130, and 140 are attached. However, base 310 may constructed in alternate configurations, such as a frame formed from metal rods or beams, or from a full sheet of metal or wood. It is desirable to have the size of the mounting frame approximately the same size as the module to allow for a greater number of modules to be packed into a given solar field. However, it is also possible for the linear actuators 120 and 130 to have a wider base than the footprint of the module to provide increased resistance against wind loads. As described previously, the tracking system may be installed without a base, and instead may be installed manually. While the mounting base 310 improves the accuracy and time required for positioning the supports 120, 130, and 140, certain installation circumstances may not be amenable to using the base 310. This may occur, for instance, where irregularity of the ground terrain would affect leveling of the base, or where the additional weight of the frame is not desirable.

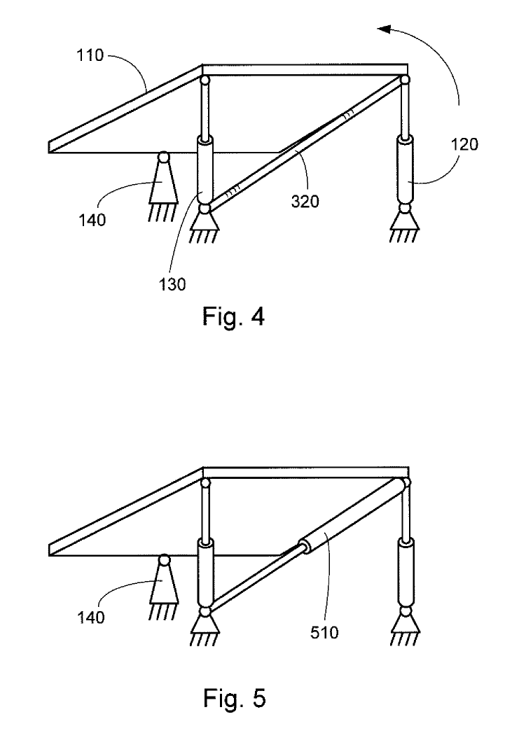

In FIG. 4, a rear perspective view of the solar tracking system is provided such that cross-brace 320 may be fully seen. As mentioned previously in conjunction with FIG. 3, cross-brace 320 connecting linear actuators 120 and 130 provides stability to actuators 120 and 130. In this exemplary illustration, cross-brace 320 is a metal rod, coupled by ball and socket joints at both ends. Due to the fixed length of cross-brace 320, the range of motion is confined to the rotation of cross-brace 320 as indicated by the arrow. This configuration may be utilized, for instance, where the rotation axis of the solar module is placed in a north-south alignment, or where minimal azimuthal changes are required. FIG. 5 shows a modification of FIG. 4, utilizing a linear actuator 510 as a cross-brace, rather than a fixed rod, to allow for an additional degree of freedom. In the configuration of FIG. 5, a wide range of tilt angles may be achieved.

It should be noted that in all figures described herein, stationary support 140 is shown to be located approximately at the midpoint of the edge which it is supporting. However, support 140 may be positioned off-center to achieve varying tilt angles of the solar module. In the case where stationary support 140 is off-center, additional structural support, such as diagonal arms extending from the support 140 to along the edge of the solar module, may be added to aid in bearing the weight of the module.

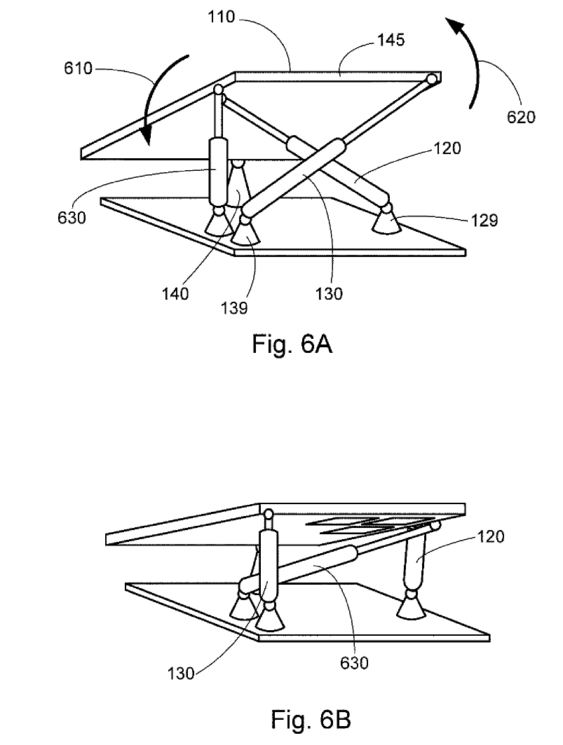

FIG. 6A illustrates yet another embodiment of the solar tracking system. In this configuration, the two linear actuators 120 and 130 form a crossed configuration rather than being positioned substantially upright as in previous designs. That is, defining the mid-line of the module 110 as a line from the bottom edge near the stationary support 140 to approximately the center of the top edge 145, each actuator is coupled to the module 110 at a point to one side of the mid-line, and coupled to the ground on the opposite side of the mid-line. Having the actuators 120 and 130 crossed provides additional stability over upright actuators, and may also allow for the solar module 110 to retract into a more horizontal position compared with upright actuators. Although the ground attachment points 129 and 139 are shown to be underneath module 110 to minimize the installation footprint, ground attachment points 129 and 139 may be positioned further apart as desired. Cross-brace 630 helps to constrain the degrees of freedom which are created by the universally pivoting joints coupling actuator 120, actuator 130, and support 140 to module 110 and to ground.

The system of FIG. 6A may be rotated into stowed position, as indicated by the arrows 610 and 620, provided that adequate clearance with the ground is present for the module to invert from a face-up to a face-down position. FIG. 6B shows the stowed position of the system of FIG. 6A, in which the module has been fully rotated so that the actuators 120 and 130 result in an uncrossed position and cross-brace 630 becomes a diagonal support.

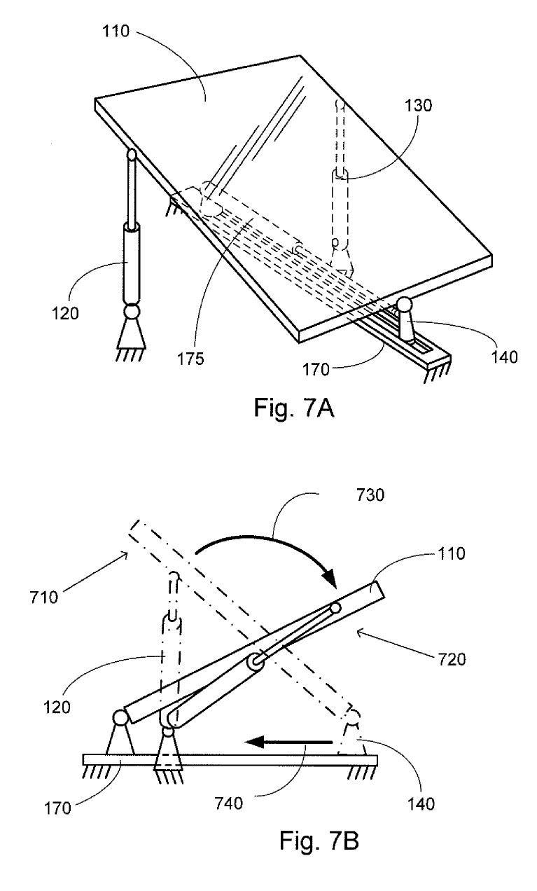

In yet another configuration of the present invention shown in FIG. 7, the “stationary” support 140 is altered to be movable along a limited line of motion. In this embodiment, support 140 is mounted on rail 170 which is constrained to ground. The movement of support 140 provides an additional degree of freedom, while also decreasing the three-dimensional space traversed by the solar module 110 compared with systems in which the support 140 is fixed to the ground. Actuator 175 moves the support 140 along the rail 170, whereby extension of the actuator 175 causes the module 110 to become more horizontal to the ground, and shortening of the actuator 175 causes the module 110 to become more vertical in orientation. In another variation not shown, component 170 may be a motorized linear slide, thus eliminating the need for actuator 175. In another embodiment, either linear actuator 120 or 130 may be replaced by a rod of fixed length. This would offer a lower-cost system with more limited range of motion.

FIG. 7B demonstrates a side view of a stowed position for the system of FIG. 7A. In FIG. 7B, the module 110 moves from an active position 710 to a stowed position 720. The stowed position is accomplished as indicated by the arrow 730. That is, linear actuator 120 and linear actuator 130 (not shown) are extended, and support 140 is translated along rail 170 as represented by arrow 740. It can be seen that this rail system occupies less space than that of FIG. 2 due to the ability of support 140 to shift position along the ground rail 170.

Although embodiments of the invention have been discussed primarily with respect to specific embodiments thereof, other variations are possible. The solar module described previously may refer to any type of solar collector, such as flat-panels, concentrators, parabolic troughs, or the like. The tracking system of this invention may be utilized for other applications such as satellite dishes or large scale telescopes. The coupling joints described herein may be replaced by other joints known in the art beyond universal joints or ball and sockets, which may result in either increased or decreased degrees of freedom as desired. Furthermore, while the extendable supports are described as linear actuators, they may be include equivalent structures such as telescoping arms, pneumatic cylinders, hydraulic rams, linear bearings, and linear motors.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A solar tracking system for moving a solar energy module, said solar energy module having an energy collection surface, comprising:
a first support arm comprising a first linear actuator having first and second ends, wherein said first end of said first linear actuator is coupled to said solar energy module;
a second support arm having first and second ends, wherein said first end of said second support arm is coupled to said solar energy module; and
a stationary support having a top end and a bottom end, wherein said top end is coupled to said solar energy module by a universally pivoting joint.

2. The solar tracking system of claim 1, wherein said first linear actuator, said second support arm, and said stationary support form a substantially triangular support base for said solar energy module.

3. The solar tracking system of claim 1, wherein said second support arm comprises a second linear actuator.

4. The solar tracking system of claim 1, further comprising a cross-brace having a top end and a bottom end, wherein said top end of said cross-brace is coupled near said first end of said first linear actuator, and wherein said bottom end of said cross-brace is coupled near said second end of said second support arm.

5. The solar tracking system of claim 4, wherein said cross-brace comprises a third linear actuator.

6. The solar tracking system of claim 1, further comprising a mounting base, wherein said second end of said first linear actuator, said second end of said second support arm, and said bottom end of said stationary support are all coupled to said mounting base.

7. The solar tracking system of claim 6, wherein said second end of said first linear actuator is coupled to said mounting base with a universally pivoting joint.

8. The solar tracking system of claim 6, wherein said mounting base comprises a metal frame.

9. The solar tracking system of claim 1, wherein said first end of said first linear actuator is coupled to said solar energy module with a universally pivoting joint.

10. The solar tracking system of claim 1, wherein said first end of said second support arm is coupled to said solar energy module with a universally pivoting joint.

11. The solar tracking system of claim 3, wherein said solar module comprises a mid-line defining a right half and a left half of said solar module;
wherein said first end of said first linear actuator is coupled to said solar module at a first attachment point on said right half, and wherein said second end of said first linear actuator is coupled to the ground at a location to the left of said mid-line of said solar module; and
wherein said first end of said second linear actuator is coupled to said solar module at a second attachment point on said left half, and wherein said second end of said second linear actuator is coupled to the ground at a location to the right of said mid-line of said solar module.

12. The solar tracking system of claim 3, wherein said first linear actuator and said second linear actuator comprise a range of motion to move said solar module into a stowed position.

13. The solar tracking system of claim 12 wherein said stowed position comprises said energy collection surface of said solar module to be facing at least partially away from the sun.

14. The solar tracking system of claim 1, wherein said energy collection surface comprises an array of solar concentrator devices.

15. The solar tracking system of claim 1, wherein said bottom end of said stationary support is coupled to a rail, wherein said rail is co-planar with the ground.

16. A method of moving a solar module, wherein said solar module is coupled to a first linear actuator, a second support arm, a stationary support, and a control system, wherein said method of moving comprises:
providing control signals from said control system to said first linear actuator and to said second support arm;
moving said first actuator from a first position to a second position; and
moving said second support arm from a first position to a second position.

17. The method of moving a solar module of claim 16, wherein said step of providing control signals comprises sensing the sun's position with photo sensors.

18. The method of moving a solar module of claim 16, wherein said second position of said first linear actuator, and said second position of said second support arm comprise a stowed position of said solar module.

19. The method of moving a solar module of claim 16, wherein said control system comprises linear encoders coupled to said first linear actuator and to said second support arm.
